(19) United States
(12) Patent Application Publication
(10) Pub. No.: US 2003/0193796 A1
(43) Pub. Date: Oct. 16, 2003

(54) Light-emitting devices

(76) Inventors: Stephen K. Heeks, Cottenham (GB); Paul R. Berger, Columbus, OH (US)

Correspondence Address: HARNESS, DICKEY & PIERCE, P.L.C., P.O. BOX 828, BLOOMFIELD HILLS, MI, 48303, US

(21) Appl. No.: 10/122,685

(22) Filed: Apr. 15, 2002

(51) Int. Cl. F21V 9/00

(52) U.S. Cl. 362/84; 362/231; 362/293

(57) ABSTRACT

The present invention relates to a light-emitting device including a plurality of regions of phosphorescent material and a plurality of individually actuable regions of organic light-emitting material. The device is capable of emitting radiation of a wavelength that can excite the phosphoresce, each region of organic light-emitting material being arranged for emitting radiation to a respective region of phosphorescent material to cause phosphorescence of the material in that region.

This invention relates to light-emitting devices, especially such devices that include phosphorescent material that can be stimulated by organic light-emitting material of the device.

One class of light-emitting devices is those that use an organic material for light emission. Light-emitting organic materials are described in PCT/WO90/13148 and U.S. Pat. No. 4,539,507, the contents of both of which are incorporated herein by reference. The basic structure of these devices is a light-emitting organic layer, for instance a film of a poly(p-phenylenevinylene (“PPV”), sandwiched between two electrodes. One of the electrodes (the cathode) injects negative charge carriers (electrons) and the other electrode (the anode) injects positive charge carriers (holes). The electrons and holes combine in the organic layer generating photons. In PCT/WO90/13-148 the organic light-emitting material is a polymer. In U.S. Pat. No. 4,539,507 the organic light-emitting material is of the class known as small molecule materials, such as (8-hydroxyquinoline)aluminium (“Alq3”). In a practical device one of the electrodes is typically transparent, to allow the photons to escape the device.

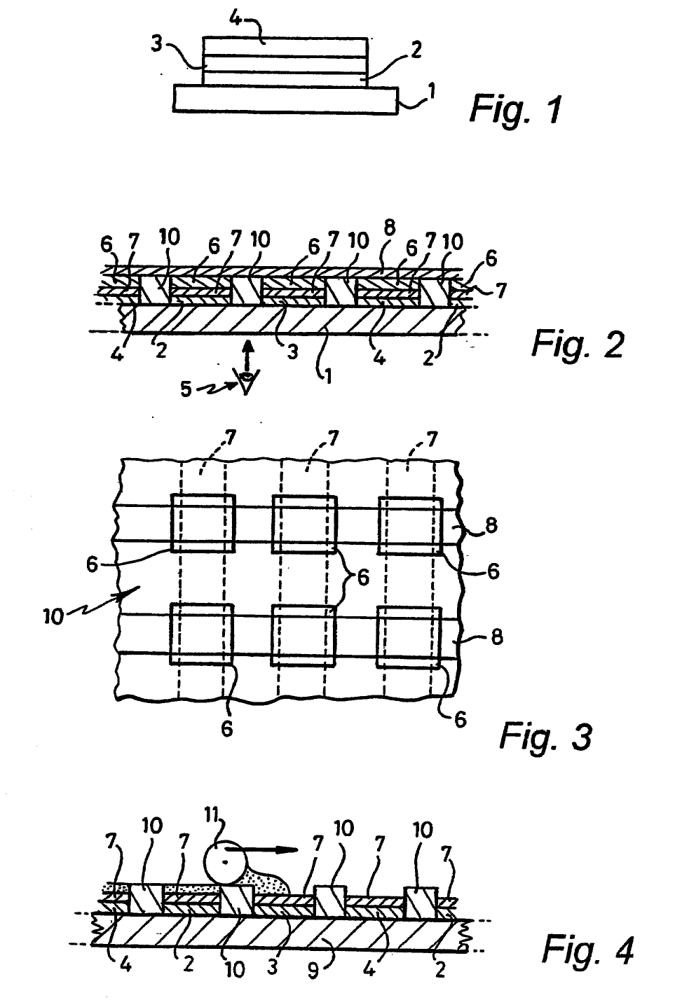

FIG. 1 shows the typical cross-sectional structure of an organic light-emitting device (“OLED”). The OLED is typically fabricated on a glass or plastic substrate 1 coated with a transparent anode electrode 2 of a material such as indium-tin-oxide (“ITO”) that is suitable for injecting positive charge carriers. Such coated substrates are commercially available. This ITO-coated substrate is covered with at least a layer of a thin film of an electroluminescent organic material 3 and a final layer forming a cathode electrode 4 of a material that is suitable for injecting negative charge carriers. The cathode electrode is typically of a metal or alloy. Other layers can be included in the device, for example to improve charge transport between the electrodes and the electroluminescent material.

The device of FIG. 1 is capable of emitting light of only a single colour. A number of approaches have been tried for forming a device that is capable of emitting light of different colours from independently controllable pixels, and that is simple to manufacture.

U.S. Pat. No. 5,874,803 describes a device having a plurality of organic light-emitting devices which are stacked and can stimulate another material to emit. That other material is said in U.S. Pat. No. 5,874,803 to be “phosphorescent”. However, this is incorrect. The effect utilised in this document is fluorescence, not phosphorescence. Furthermore, the structure of the device of U.S. Pat. No. 5,874,803 is cumbersome and would be expected to be highly problematic to manufacture.

Another approach to manufacturing multi-colour devices has been to use colour filters over selected parts of the device (see, for example, 1998 SID, Hosokawa et al., pp 7-10). However, this can reduce the efficiency of the device.

In another approach, multi-colour devices have been made in which there are independently controllable light emitting regions of different organic light-emitting polymers—for example regions of red-emitting polymer, regions of green-emitting polymer and regions of blue-emitting polymer. However, these devices are complex to design, because of the difficulties of formulating organic materials that are capable of emitting the desired colours; and difficult to manufacture, because of the need to precisely deposit or pattern the various organic materials.

Conventional cathode ray tubes address the above problems by the use of a screen that is coated with regions of red-, green- and blue-phosphorescent materials. The phosphorescent materials can be excited by an electron gun to cause them to emit light to show a desired image. One problem with cathode ray tube displays is that they occupy significant depth due to the space that is needed between the electron gun and the phosphor screen. Therefore, another approach has been to replace the electron gun with a pixellated field emitting structure in which each pixel is aligned with a pixel of the phosphorescent screen and has a field emitting Spindt tip which can individually launch electrons into the corresponding phosphor pixel. However, a field emitting display (FED) of this type suffers from both a difficulty in building uniform Spindt tips across an entire display and the lack of robustness for each tip to electromigration due to the strong localised electric fields. Also FED technology requires high voltage and there are encapsulation difficulties associated with maintaining the high vacuum in the display cell.

Therefore, there is a need for an improved design of display.

According to one aspect of the present invention there is provided a light-emitting device comprising: a region of phosphorescent material; and a region of organic light-emitting material capable of emitting radiation of a wavelength that can excite the phosphorescent material to phosphoresce.

According to a second aspect of the present invention there is provided a method for forming a light-emitting device, comprising: depositing a plurality of regions of phosphorescent material on a light-transmissive substrate; and forming a plurality of individually actuable regions of organic light-emitting material capable of emitting radiation of a wavelength that can excite the phosphorescent material to phosphoresce, each region of organic light-emitting material being arranged for emitting radiation to a respective region of phosphorescent material to cause phosphorescence of the material in that region.

According to one embodiment of the invention, the light-emitting device comprises a plurality of regions of phosphorescent material; and a plurality of individually actuable regions of organic light-emitting material capable of emitting radiation of a wavelength that can excite the phosphorescent material to phosphoresce, each region of organic light-emitting material being arranged for emitting radiation to a respective region of phosphorescent material to cause phosphorescence of the material in that region.

Suitably some of the regions of phosphorescent material comprise a first phosphorescent material capable of emitting light of a first colour by phosphorescence, and other of the regions of phosphorescent material comprise a second phosphorescent material capable of emitting light of a second colour by phosphorescence. Preferably other of the regions of phosphorescent material comprise a third phosphorescent material capable of emitting light of a third colour by phosphorescence. In a most preferred arrangement the first colour is red, the second colour is green and the third colour is blue, but colours and other colour combinations may be used. The phosphorescent materials are arranged into groups such as pixels. Each group suitably comprises a region of the first phosphorescent material, a region of the second phosphorescent material and a region of the third phosphorescent material.

The substrate may be substantially planar. Alternatively the substrate may be non-planar: for example, the substrate may include formations to assist proper deposition of the phosphorescent material. The substrate may be rigid or flexible (e.g. if it is formed of a plastics material).

Each region of organic light-emitting material suitably corresponds to a single one of the phosphorescent regions Each region of organic light-emitting material is suitably capable of emitting light to substantially a single one of the phosphorescent regions. Each region of organic light-emitting material is preferably located so as to overlap the corresponding region of phosphorescent material. Most preferably the overlap is in a direction perpendicular to the substrate, at least at the location of that region.

The said radiation of a wavelength that can excite the phosphorescent material to phosphoresce is suitably and ultraviolet or deep blue wavelength.

The light-emitting material is preferably a polymer material. The light-emitting material is preferably a semiconductive and/or conjugated polymer material. Alternatively the light-emitting material could be of other types, for example a sublimed small molecule films. The or each organic light-emitting material may comprise one or more individual organic materials, suitably polymers, preferably fully or partially conjugated polymers. Example materials include one or more of the following in any combination: poly(p-phenylenevinylene) (“PPV”), poly (2-methoxy-5 (2′-ethyl) hexyloxyphenylenevinylene) (“MEH-PPV”), one or more PPV-derivatives (e.g. di-alkoxy or di-alkyl derivatives), polyfluorenes and/or co-polymers incorporating polyfluorene segments, PPVs and related co-polymers, poly(2,7-(9,9-di-n-octylfluorene)-(1,4-phenylene-((4-secbutylphenyl)imino)-1,4-phenylene)) (“TFB”), poly(2,7-(9,9-di-n-octylfluorene)-(1,4-phenylene-((4-methylphenyl)imino)-1,4-phenylene-((4-methylphenyl)imino)-1,4-phenylene)) (“PFM”), poly(2,7-(9,9-di-n-octylfluorene)-(1,4-phenylene-((4-methoxyphenyl)imino)-1,4-phenylene-((4-methoxyphenyl)imino)-1,4-phenylene)) (“PFMO”), poly (2,7-(9,9-di-n-octylfluorene) (“F8”) or (2,7-(9,9-di-n-octylfluorene)-3,6-Benzothiadiazole) (“F8BT”). Alternative materials include small molecule materials such as Alq3. The light-emitting region may include two or more such materials.

The device suitably comprises anode and cathode electrodes arranged so that each light-emitting region lies between an anode and a cathode electrode. The electrodes are preferably arranged (with or without additional circuitry such as thin film transistor active matrix switching means) so that each light-emitting region can be individually controlled. One or more charge-transport layers may be provided between each light-emitting region and one or both of the electrodes, or integrated into the light-emitting regions. The or each charge transport layer may suitably comprise one or more polymers such as polystyrene sulphonic acid doped polyethylene dioxythiophene (“PEDOT:PSS”), poly(2,7-(9,9-di-n-octylfluorene)-(1,4-phenylene-(4-imino(benzoic acid))-1,4-phenylene-(4-imino(benzoic acid))-1,4-phenylene)) (“BFA”), polyaniline and PPV.

The device of the form set out above is suitably a full colour display.

The present invention also provides a display device of the form set out above, and an electronic article—for example a portable computer, display screen or television—having such a display device. Such an article suitably includes a display driver for receiving a signal defining an information to be displayed and causing the light-emitting regions of the device to be controlled to excite the phosphorescent regions to display the information.

The present invention will now be described by way of example with reference to the accompanying drawings, in which:

FIG. 2 shows a cross-section of a display device;

FIG. 3 shows a plan view of the device of FIG. 2; and

FIG. 4 illustrates a step in the formation of the device of FIG. 2.

In the display device of FIGS. 2 and 3 a substrate 1 carries phosphorescent material 2, 3, 4. The regions of phosphorescent material are separate. Regions 2 comprise red phosphorescent material. Regions 3 comprise green phosphorescent material. Regions 4 comprise blue phosphorescent material. The device of FIG. 2 is intended to be viewed in the viewing direction indicated at 5. Behind the phosphorescent regions (with respect to the viewing direction) are individually controllable regions 6 of organic light-emissive material. Anode 7 and cathode 8 electrodes are arranged on either side of each controllable region of light-emitting material to allow a voltage to be applied across it. When a suitable voltage is applied across it each region of light-emitting material emits light of a wavelength that is capable of stimulating phosphorescence from the corresponding phosphorescent region. Therefore a selected one of the phosphorescent regions can be caused to phosphoresce, and thereby emit light of the colour with which it phosphoresces, by activation of the corresponding region of light-emitting material.

Phosphorescence is the emission of radiation by a material due to bombardment by particles or radiation from another source which excites carriers to a triplet state, as opposed to the singlet state associated with fluorescence. The lifetime of triplet states is generally longer than singlet states, meaning that the phosphorescent emission generally continues after the bombardment has ceased. Conventionally, the lifetime of the excitation of the atoms etc. in phosphorescence is taken to be greater than 10⁻⁸ s.

The device of FIGS. 2 and 3 has great advantages over prior colour displays. In the device of FIGS. 2 and 3, unlike many prior colour displays employing organic light-emitting materials, there is no need to precisely tailor the emission colours of the organic light-emitting regions to obtain the precise red, green and blue colours that are needed for a high quality full colour RGB display. In the device of FIGS. 2 and 3 the emission colours are dependant on the phosphors that are used; and the phosphor technology required to produce those emission colours is very well established after many years of research in the CRT field. Therefore, it is straightforward to design the device to produce desired red, green and blue emission colours for accurate full colour display. Unlike conventional phosphorescent cathode ray tube displays the device of FIGS. 2 and 3 can be made very thin, allowing it to be used for flat panel displays in, for example, portable computers.

FIG. 4 illustrates one of the methods available for forming the device of FIGS. 2 and 3. The phosphor regions are deposited on a substrate 9 of a transparent material, for example a glass plate. The glass plate could be a sheet of sodalime or borosilicate glass of a thickness of, for instance, 1 mm. Instead of glass other materials such as Perspex could be used. The phosphor regions may be deposited in any conventional way as is well known in the manufacture of RGB cathode ray tubes (CRTs). The arrangement of the phosphor regions is preferably as for a conventional RGB CRT, wherein each pixel of the display comprises closely arranged regions of red-, green- and blue-emitting phosphor and the pixels of the display are arranged in a grid of orthogonal rows and columns. However, different arrangements are possible. For example, each pixel could comprise phosphors of other emission colours; each pixel could comprise any number of emission colours, for example one, two, three, four or five emission colours; different pixels could comprise different numbers of phosphors; and/or the pixels could be arranged in other patterns. It should be noted that one or more of the regions of phosphor material may be contiguous. For example, phosphor regions of the same or different colours may be individually deposited so that they abut each other, or a plurality of phosphor regions of the same colour may be deposited as a single mass of phosphorescent material, for example as a stripe running across the substrate, separate parts of which constitute different regions associated with respective pixels.

Over the phosphor regions the anode electrodes 7 are deposited as strips which run in a first direction (as rows, say) across the substrate. The device as illustrated is addressable by a passive matrix addressing scheme, so the anode strips intersect all the phosphorescent regions in each row. Other addressing schemes such as active matrix addressing could be used. The anode electrodes are light-transmissive and preferably transparent. The anode electrodes could be formed of, for example ITO or tin oxide (TO). For efficient charge injection into the organic light-emitting material it is preferred that the anode electrodes have a work function of 3.5 eV or more. The thickness of an ITO coating is suitably around 150 nm and the ITO suitably has a sheet resistance of between 10 and 30 Ω/□, preferably around 15 Ω/□.

At the locations between the phosphor regions banks 10 of electrically insulating material are deposited. The banks may be formed before or after deposition of the phosphors. The banks may, for examples be made of SiO2 or a polymer material. The banks could be formed by deposition of a uniform sheet of material which is subsequently selectively removed, for example by etching, to give the desired pattern, or by selective deposition, for example through a shadow mask. The banks could be applied as a laminate. The banks define individual wells over each region of phosphorescent material, which can later be used as described below to assist in defining the extent of the regions 6 of light-emitting material. To resist electrical cross-talk it is preferred that the banks are electrically insulating—for example formed of or including a coating of an insulating material. To resist optical cross-talk it is preferred that the banks are opaque or semi-opaque.

A light-emitting polymer material can then be deposited over the structure so that it descends into the wells defined by the banks. The light-emitting material is preferably deposited in fluid form, for example dissolved in a solvent. This may be done by spin coating, blade coating or by drawing a roller or push rod 11 (as shown in FIG. 4) across the upper surface of the banks to force the light-emitting material across and into the wells and ensure that each well is sufficiently filled. The solvent can then be evaporated to leave light-emitting material in the wells.

In order to excite the phosphorescent material light of a relatively high-energy wavelength is generally required. Radiation in the deep blue or ultra-violet region of the spectrum (e.g. in the range from 405 to 550 nm) is generally needed. Suitable organic light-emitting materials for providing such emission include polyfluorenes such as F8 itself or F8 modified with a second group such as an anthracene or a stilbene, TFB (di-(p-phenylene)-4-s-butylphenylamine) or PFF (N,N′-di (p-phenylene)-N,N′-di-(3-trifluoromethylphenyl))-1,4-phenylamine diamine) all of which emit in the region from 405 to 500 nm; or PFMO (N,N′-di(p-phenylene)-N,N′-di-(4-methoxyphenyl)-1,4-phenylene diamine) or PFB (N,N′-di(p-phenylene)-N,N′-di(4-n-butylphenyl)-1,4-phenylamine diamine) both of which emit in the region from 440 to 550 nm. It should be noted that it is not necessary for the entire emission spectrum of the selected material to lie in the ultra-violet—merely that sufficient stimulation of the phosphorescent material can occur. It should also be noted that although the display of- FIGS. 2 and 3 provides a number of different emission colours, the same organic light-emitting material may be used at each individually controllable region.

Then the cathode electrodes 8 are deposited as strips over the light emitting material. In this passive matrix embodiment the cathode electrode strips 7 run in a second direction (as columns, say) across the substrate orthogonal to the anode rows. The cathode strips intersect all the phosphorescent regions in each column, so that by applying a suitable voltage between a cathode strip and an anode strip a selected one of the light-emitting regions can be caused to emit light to stimulate phosphorescence of the corresponding phosphorescent region. The cathode electrodes could be formed of, for example a layer of calcium adjacent the light-emitting material, capped by a layer of aluminium. For efficient charge injection into the organic light-emitting material it is preferred that the anode electrodes have a work function of 3 eV or less.

Contacts are then made to the electrodes and the device is encapsulated, for example in epoxy, for environmental protection.

The device can be driven by a suitable passive matrix drive circuit. When one of the light-emitting regions is cause to emit it bombards the adjacent phosphorescent region with relatively high energy photons which are downconverted by the phosphorescent material for the desired colour emission from the device towards a viewer. Preferably, the device is arranged so that none of the light emitted by the light-emitting regions reaches a viewer directly.

Performance of the device may be found to be improved by the inclusion of charge transport material such as PEDOT:PSS or polyaniline between one or both of the electrodes and the light-emitting material.

In comparison to prior phosphorescent display devices, the display device of FIGS. 2 and 3 can be made especially thin. If the substrate on which the display is formed were flexible then the display itself could be flexible.

Other methods could be used to forming a device using the principles of that of FIGS. 2 and 3. For example, the phosphorescent regions could be deposited in the appropriate locations on to an already formed organic light-emitting unit, or an already formed organic light-emitting unit could be married in the appropriate interlocation to a phosphorescent structure comprising the phosphorescent regions already formed on a substrate.

Some or all of the phosphorescent regions may advantageously be formed of an organic material. Use of organic phosphorescent material offers a number of advantages. An organic phosphorescent material is likely to be processable by the same routes as or similar routes to those used for the other organic materials of the device. An organic phosphorescent material may be more compatible with the other organic materials of the device than an inorganic phosphor may be. An organic phosphor is likely to be readily flexible, allowing a flexible display to be formed. Suitable organic phosphorescent materials include porphyrins such as PtOEP (platinum octaethylporphyrin) and the like. Such materials are discussed in, for example, Highly Efficient Phosphorescent Emission from Organic Electroluminescent Devices (Baldo et al., Nature vol. 395, p151), High Luminescence Gold(I) and Copper(I) Complexes with a Triplet excited State for Use in Light-Emitting Diodes (Ma et al., Adv. Mater. 1999, 11, No. 10, p 852) and Harvesting Singlet and Triplet Energy in Polymer LEDs (Cleave et al., Adv. Mater. 1999, 11, No. 4, p285).

Numerous modifications may be made to the device described above. For example, the locations of the anode and cathode electrodes could be exchanged, and the arrangement of the phosphorescent regions and the light-emitting region corresponding to each one could be altered for other applications.

The applicant draws attention to the fact that the present invention may include any feature or combination of features disclosed herein either implicitly or explicitly or any generalisation thereof, without limitation to the scope of any of the present claims. In view of the foregoing description it will be evident to a person skilled in the art that various modifications may be made within the scope of the invention.

1. A light-emitting device comprising:
a region of phosphorescent material; and
a region of organic light-emitting material capable of emitting radiation of a wavelength that can excite the phosphorescent material to phosphoresce.

2. A light-emitting device according to claim 1 and comprising:
a plurality of regions of phosphorescent material; and
a plurality of individually actuable regions of organic light-emitting material capable of emitting radiation of a wavelength that can excite the phosphorescent material to phosphoresce, each region of organic light-emitting material being arranged for emitting radiation to a respective region of phosphorescent material to cause phosphorescence of the material in that region.

3. A light-emitting device as claimed in claim 2, wherein some of the regions of phosphorescent material comprise a first phosphorescent material capable of emitting light of a first colour by phosphorescence, and other of the regions of phosphorescent material comprise a second phosphorescent material capable of emitting light of a second colour by phosphorescence.

4. A light-emitting device as claimed in claim 3, wherein other of the regions of phosphorescent material comprise a third phosphorescent material capable of emitting light of a third colour by phosphorescence.

5. A light-emitting device as claimed in claim 4, wherein the first colour is red, the second colour is green and the third colour is blue.

6. A light-emitting device as claimed in claim 4 or 5, wherein the phosphorescent materials are arranged into groups, each group comprising a region of the first phosphorescent material, a region of the second phosphorescent material and a region of the third phosphorescent material.

7. A light-emitting device as claimed in any preceding claim, wherein the substrate is substantially planar.

8. A light-emitting device as claimed in any preceding claim, wherein each region of organic light-emitting material is disposed so as to overlap the corresponding region of phosphorescent material.

9. A light-emitting device as claimed in any preceding claim, wherein the said radiation of a wavelength that can excite the phosphorescent material to phosphoresce is ultraviolet or deep blue light.

10. A light-emitting device as claimed in any preceding claim, wherein the organic light-emitting material is polymer material.

11. A light-emitting device according to any preceding claim, wherein said phosphorescent material is an organic material.

12. A light-emitting device according to claim 11, wherein said organic material is a porphyrin.

13. A light-emitting device according to claim 12, wherein said organic material is platinum octaethylporphyrin.

14. A display device incorporating a light-emitting device as claimed in any preceding claim.

15. An electronic article comprising a display device as claimed in claim 14.

16. A method for forming a light-emitting device, comprising:
depositing a plurality of regions of phosphorescent material on a light-transmissive substrate; and
forming a plurality of individually actuable regions of organic light-emitting material capable of emitting radiation of a wavelength that can excite the phosphorescent material to phosphoresce, each region of organic light-emitting material being arranged for emitting radiation to a respective region of phosphorescent material to cause phosphorescence of the material in that region.
